(19) United States
(12) Patent Application Publication
(10) Pub. No.: US 2013/0168702 A1
(43) Pub. Date: Jul. 4, 2013

(54) Method For Preparing a GaAS Substrate For A Ferromagnetic Semiconductor, Method for Manufacturing One Such Semiconductor, Resulting Substrate and Semiconductor, And Uses Of Said Semiconductor

(71) Applicants: André Barski, Moirans (FR); Matthieu Jamet, Voiron (FR)

(72) Inventors: André Barski, Moirans (FR); Matthieu Jamet, Voiron (FR)

(21) Appl. No.: 13/818,168

(22) PCT Filed: Jul. 15, 2011
(86) PCT No.: PCT/IB11/53170

§ 371 Date: Mar. 12, 2013

(30) Foreign Application Priority Data
Aug. 24, 2010 (FR) 10 03426

(51) Int. Cl. H01L 43/12; H01L 43/10; H01L 21/02

(52) U.S. Cl. CPC H01L 43/12; H01L 21/02658; H01L 43/10
USPC 257/79; 438/478; 257/631; 438/3; 257/183

(57) ABSTRACT

A method is provided for preparing a surface of a GaAs substrate (001) such that it can receive a ferromagnetic semiconductor deposited by epitaxy, as well as a substrate thus prepared, method for manufacturing one such semiconductor deposited on the substrate, the resulting semiconductor, and uses thereof. The preparation method renders the surface capable of receiving an epitaxially deposited ferromagnetic semiconductor which may include semiconductors from groups III-V, IV and II-VI of the periodic table, with the exception of GaAs, and which also includes at least one magnetic element of manganese, iron, cobalt, nickel and chromium. The method includes vacuum deoxidation of the surface under a reduced germanium-based flux such that, following desorption of the arsenic and gallium oxide from the said surface, the latter has a single-domain 2×1 reconstruction and is sufficiently planar and arsenic-depleted to prevent any diffusion of arsenic from the substrate to the subsequently deposited semiconductor.

The present invention relates to a method for preparing a surface of a substrate based on GaAs (001) in order to make it capable of receiving a ferromagnetic semiconductor deposited by epitaxy, to a substrate prepared in this way, to a method for manufacturing such a semiconductor deposited on this substrate, to this semiconductor obtained in this way, and to its uses. The invention applies to semiconductors of groups III-V, IV-IV or II-VI of the periodic table, and in particular to group IV semiconductors based on germanium.

The injection of a spin-polarized current of carriers into a semiconductor, which is characterized by an excess of one of the two populations of carriers present (for example that of spin parallel or “spin up”) has been the subject of numerous publications. For example, the electronic components described in the article Datta and Das, Applied Physics Letters, 56, 665, 1990 may be mentioned by way of example.

The use of this injection of a spin-polarized current is of great interest in microelectronics, but its development suffers from the lack of suitable materials for constituting the current injection electrode.

Specifically, although the usual ferromagnetic metals, such as iron and a number of its alloys, have some of the requisite qualities such as high spin polarization and a ferromagnetic behavior at room temperature, their electrical resistance is several orders of magnitude different to that of semiconductors, which entails great implementation difficulties and makes it necessary to carry out current injection by the tunnel effect. This has the drawback of requiring the growth of a hybrid heterostructure which is difficult to produce, of the semiconductor/tunnel-effect barrier/ferromagnetic metal type.

On the other hand, there are so called diluted magnetic semiconductors (abbreviated to “DMS”) which do not present this drawback of having a resistivity very different to that of ordinary semiconductors. These “DMS” typically consist of a semiconductor matrix from groups III-V, IV-IV or II-VI in which magnetic impurities such as manganese, iron, chromium, cobalt or nickel are diluted.

The patent document WO-A1-2007/090946 in the name of the Applicant has demonstrated that deposition by molecular beam epitaxy (“MBE”) at low temperature, on a monocrystalline germanium substrate, of a group IV semiconductor such as germanium furthermore comprising a magnetic element such as manganese, this semiconductor being deposited in the form of a thin film laterally modulated by continuous ferromagnetic nanocolumns which are rich in manganese and which are separated from one another by a matrix which has a low manganese content, makes it possible to impart exceptional ferromagnetic properties to this semiconductor, for example of the GeMn type, which are characterized by a Curie temperature that can exceed 350 K or even 400 K.

However, if the magnetotransport properties in such a semiconductor are intended to be studied, it is necessary for the charge carriers to remain confined in the GeMn thin film deposited on the substrate by applying an electric current, and it is known that there is no semi-insulating germanium substrate of sufficient quality to carry out subsequent GeMn epitaxy on the surface of this substrate with the ferromagnetic properties desired for this semiconductor.

Although there are insulating GaAs substrates of excellent crystallographic quality, which could theoretically be used for the growth of GeMn, in practice it turns out that the preparation of the surface of these known GaAs substrates does not make this surface suitable for the deposition of GeMn by epitaxy, in particular because this GaAs surface is rich in arsenic after its preparation, which makes the strong n-type dopant constituted by arsenic diffuse into the GeMn layer while undesirably doping the latter and therefore altering the magnetic properties of the GeMn semiconductor.

The following conventional methods for the preparation of a GaAs substrate may be cited, which have this common drawback of leading to a high arsenic level of the GaAs surface.

According to a first method, for example used with a view to homoepitaxy of GaAs, the GaAs substrate is heated in a vacuum to a temperature of the order of 600° C. under an arsenic flow, which makes it possible to deoxidize the surface of the substrate by desorption of arsenic and gallium oxide and to maintain good planarity of this surface. By this heat treatment, an arsenic-rich 2×4 reconstructed surface of GaAs (001) is formed (given that without an arsenic flow, the surface of the substrate would be depleted of arsenic and consequently would become rough, which would impair the quality of the subsequent deposition by epitaxy). If a semiconductor film based not on GaAs but on GeMn is deposited by epitaxy on this arsenic-rich surface, it is found that this GeMn film does not have the desired magnetic properties. However, an arsenic evaporation source cannot be placed in an epitaxy unit dedicated to the growth of group IV semiconductors, and more particularly GeMn, because arsenic would irremediably lead to strong pollution of the deposited semiconductor owing to excessive residual n-type doping with the arsenic and the corresponding low activation energy (14 meV).

According to a second method, it is possible to use GaAs (001) surfaces prepared by molecular beam epitaxy under arsenic flow and covered with a thin film of amorphic arsenic, with transfer of the GaAs sample prepared in this way in air then placement of this sample in a GeMn epitaxy unit. The layer of amorphic arsenic is then evaporated therein, which leads to an arsenic-rich 2×4 reconstructed GaAs surface being obtained and, as before, the deposition of GeMn on this surface leads to strong diffusion of arsenic into the GeMn film, which becomes “n-type” owing to this doping and therefore no longer has the desired structural and magnetic properties.

In order to overcome this problem, it has been attempted to transfer in a vacuum the GaAs substrate prepared according to the second method from an epitaxy unit dedicated to GaAs to another epitaxy unit dedicated to GeMn, but without succeeding to avoid this pollution of the GeMn since with the second method the 2×4 reconstructed GaAs surface is still rich in arsenic and therefore diffuses into the GeMn film. Furthermore, the second method requires either coupling of the two units by ultrahigh vacuum connection, or provision of a special chamber referred to as an “ultrahigh vacuum transfer chamber”, these solutions being very expensive and difficult to implement.

It is an object of the present invention to overcome all the aforementioned drawbacks, and this object is achieved in that the Applicant has surprisingly discovered that vacuum deoxidation of the surface of a substrate based on GaAs (001) under a small germanium-based flow, comprising desorption of the arsenic and gallium oxide of this surface, makes it possible to obtain a monodomain 2×1 reconstruction for this surface at the end of desorption, which is furthermore sufficiently planar and depleted of arsenic to avoid any diffusion of arsenic from this substrate prepared in this way to a ferromagnetic semiconductor subsequently deposited by epitaxy, which is selected from the group consisting of those of groups III-V, IV-IV and II-VI of the periodic table with the exception of GaAs and furthermore comprises at least one magnetic element selected from the group consisting of manganese, iron, cobalt, nickel and chromium.

The term “substrate based on GaAs (001)” is intended in the present description to mean any gallium arsenide substrate, doped or undoped, which specifically has a 001 orientation (i.e. in the well-known way parallel to the xy plane and intersecting the z axis) in contrast to the so-called A or B (111) orientation, to which the present invention does not relate.

The term “monodomain 2×1 reconstruction” is intended in the known way to mean an arrangement of the atoms on the GaAs surface which form bonds to compensate for the break in continuity of the crystal, which forms a monodomain surface, that is to say one of very high quality. This monodomain 2×1 reconstruction which appears after the deoxidation of the substrate has been precisely demonstrated by the applicant by the technique of high-energy electron diffraction (RHEED: Reflection High-Energy Electron Diffraction).

It will be noted that, further to a low level of arsenic making it possible to avoid pollution of the semiconductor film subsequently deposited, this GaAs (001) surface specifically reconstructed in a monodomain 2×1 fashion has excellent planarity with a view to the subsequent deposition of this semiconductor by epitaxy, unlike the aforementioned prior art.

According to another characteristic of the invention, this method is carried out in a molecular beam epitaxy unit dedicated to the subsequent deposition of said ferromagnetic semiconductor, for example in a unit dedicated to the deposition of a semiconductor of the GeMn type.

According to another characteristic of the invention, this surface preparation method furthermore comprises the following steps, carried out in said epitaxy unit before said deoxidation and preferably at a temperature of between 200 and 300° C.:

a) vacuum heating of the substrate, particularly in order to desorb the water and molecules of CO and CO₂ from the surface, then

b) deposition of a germanium thin film on the surface treated in this way.

It will be noted that this surface preparation method according to the invention is thus highly suitable for the epitaxy of the semiconductor on this substrate surface, and does not require complex and consequently expensive additional means.

Advantageously, said germanium flow at the substrate during the deoxidation may be between 0.9×10⁻⁸ Torr and 1.3×10⁻⁸ Torr, and this flow corresponds to a germanium growth rate which may be between 0.10 nm/min and 0.20 nm/min.

Preferably, the temperature of the substrate during the deoxidation is between 500 and 600° C., and is more preferably substantially equal to 550° C.

According to another preferred characteristic of the invention, upon appearance of said monodomain 2×1 reconstruction for the surface, said germanium flow is stopped and the temperature of the substrate is lowered to a value which is close to that used for the subsequent deposition of the ferromagnetic semiconductor and which is preferably between 80 and 200° C., and for example between 90 and 100° C. in the case in which this semiconductor is based on GeMn.

Preferably, the substrate is subjected to said germanium flow during the deoxidation for a time of between 5 min and 6 min, in order to finally obtain a Ge thin film with a thickness of less than 1 nm on said surface of the substrate.

Thus, a substrate according to the invention based on GaAs (001) has its surface which is capable of receiving a ferromagnetic semiconductor, deposited by epitaxy, which is selected from the group consisting of the semiconductors of groups III-V, IV and II-VI of the periodic table with the exception of GaAs and which furthermore comprises at least one magnetic element selected from the group consisting of manganese, iron, cobalt, nickel and chromium, and this surface has a monodomain 2×1 reconstruction and has a sufficiently low arsenic content to avoid any diffusion of arsenic from said surface to this ferromagnetic semiconductor.

According to another characteristic of the invention, this substrate is such that its surface is covered with a germanium thin film with a thickness preferably of less than 1 nm.

A method according to the invention for manufacturing a ferromagnetic semiconductor which is selected from the group consisting of the semiconductors of groups III-V, IV and II-VI of the periodic table with the exception of GaAs (preferably being based on germanium) and which comprises at least one magnetic element such as manganese, iron, cobalt, nickel and chromium, comprises deposition of this semiconductor by molecular beam epitaxy (MBE) on a substrate as defined and prepared as indicated above, the temperature of which during the growth of the crystals is between 80 and 200° C., and preferably between 90 and 100° C. in the case in which this semiconductor is based on GeMn.

Advantageously, this deposition by epitaxy may be carried out in ultrahigh vacuum by evaporation of the germanium and of said at least one magnetic element from solid sources onto the substrate, the semiconductor deposited in this way comprising ferromagnetic nanocolumns rich in this element, which are perpendicular to said surface (i.e. parallel to the growth direction of the crystals) and which are separated from one another by a matrix that has a low content of this element, as indicated in the aforementioned document WO-A1-2007/090946, with the very high Curie temperatures mentioned in this document being obtained.

It will be noted that the use of a GaAs (001) surface which has both a low arsenic content and good planarity is necessary in order to succeed in depositing layers of such a ferromagnetic semiconductor. In particular, if this GaAs surface were even somewhat rough, then the nanocolumns deposited would no longer be parallel to the growth direction of the crystals and the epitaxy grown layer or layers would no longer have the desired ferromagnetic properties.

It will also be noted that the aforementioned temperature of the substrate during the deposition of the semiconductor, which is low in comparison with crystal growth temperatures commonly used (in particular for the epitaxy of a group IV semiconductor, which is ordinarily carried out at a temperature of between 450 and 650° C.), makes it possible to stabilize the metastable semiconductor phases, or aforementioned nanocolumns rich in the magnetic element (e.g. Mn).

A ferromagnetic semiconductor according to the invention is selected from the group consisting of the semiconductors of groups III-V, IV and II-VI of the periodic table with the exception of GaAs, and it comprises at least one magnetic element selected from the group consisting of manganese, iron, cobalt, nickel and chromium, this semiconductor preferably being based on germanium, and even more preferably based on GeMn.

According to the invention, this semiconductor is deposited by molecular beam epitaxy on a surface of a substrate as defined above, and it comprises nanocolumns rich in this element, which are substantially perpendicular to said surface and which are separated from one another by a matrix that has a low content of this element.

The use according to the invention of such a ferromagnetic semiconductor may advantageously consist in injecting spins into the substrate prepared in this way based on GaAs (001), for example so that this substrate emits light in the form of light-emitting diodes while combining the emission of the light with selective spin-polarized injection. Specifically, the material GaAs, which is a direct-gap material, has the advantage of being an excellent emitter of light.

Another use according to the invention of such a ferromagnetic semiconductor may advantageously consist in producing transistors operating with spin-polarized current, this current flowing in the semiconductor deposited on this substrate based on GaAs (001).

These uses are given only by way of examples, it being understood that other uses of this ferromagnetic semiconductor deposited on a GaAs (001) substrate may be envisioned.

The aforementioned characteristics of the present invention, and others, will be better understood upon reading the following description of an exemplary embodiment of the invention, given by way of illustration and in a non-limiting manner.

An example of the manufacture of the ferromagnetic semiconductors according to the invention of the GeMn type will be described below, in each of which the discontinuous ferromagnetic GeMn phase was obtained by low-temperature molecular beam epitaxy after a specific preparation of the surface of a GaAs (001) substrate.

First, the surface of this substrate is prepared by carrying out the following successive steps in an epitaxy unit dedicated to the “MBE” epitaxy of GaMn:

a) the GaAs (001) substrate was heated in a vacuum to 250° C. in this epitaxy unit for two hours in order to desorb the water and the CO and CO₂ molecules therefrom,

b) a thin film of germanium with a thickness equal to 0.5 nm was deposited on this GaAs (001) surface at 250° C., then

c) deoxidation of the GaAs (001) substrate was carried out in a slight germanium flow for 5 to 6 min (the Ge flow at the substrate was 1.1×10⁻⁸ Torr and corresponded to a Ge growth rate of 0.15 nm/min) at a temperature of the order of 550° C. for this substrate, given that upon appearance of a monodomain 2×1 reconstruction (observed by “RHEED”, i.e. high-energy electron diffraction) which characterized the end of desorption of the gallium and arsenic oxide, the Ge flow was stopped and the temperature of the substrate was lowered to the temperature of the GeMn deposition.

This heat treatment generated a layer of germanium on the surface of the GaAs (001) substrate with a thickness of less than 1 nm.

Secondly, a layer of GeMn with a thickness equal to 80 nm was deposited on this substrate prepared in this way, and in the same epitaxy unit, at a temperature of from 90 to 100° C. for this substrate, by means of “MBE” epitaxy. In this embodiment in an ultrahigh vacuum and at low temperature, the germanium and the manganese were evaporated from solid sources onto this substrate, by using germanium and manganese partial pressures respectively of 1.8 10⁻⁸ Torr and 4 10⁻⁸ Torr in the flow at the substrate. Thus, the deposition rate of the GeMn semiconductor was of the order of 1.3 nm/min, and the average manganese concentration was 6% as an atomic fraction.

Under these growth conditions, a GeMn semiconductor was obtained incorporating a discontinuous phase in the form of a thin film in which lateral modulation of the manganese composition was observed in the form of ferromagnetic nanocolumns perpendicular to the plane of the thin film, each of which consists of an alloy richer in manganese than the matrix surrounding them, in the manner of the thin film illustrated in FIGS. 1 and 2 of the aforementioned document WO-A1-2007/090946.

By methods of composition analysis in depth, such as Auger spectroscopy and secondary ion mass spectroscopy (SIMS), the Applicant has established on the one hand the presence of traces of germanium at the interface GaAs substrate/deposited GeMn layer and, on the other hand, the absence of arsenic diffusion into the deposited GeMn layer.

In general, with reference to the present invention, it will be noted that controlling the germanium flow for the deoxidation step of the surface of the GaAs (001) substrate, the temperature of this substrate during the subsequent epitaxy of the semiconductor and of the respective flows of the or each semiconductor element (e.g. Ge) and of the or each magnetic element (e.g. Mn) and of the deposited thickness of the semiconductor are critical for carrying out epitaxy with these nanocolumns rich in magnetic element (e.g. Mn), and that these parameters may be modified to a certain extent in order to obtain different dimensions of the nanocolumns, for example with a density and/or concentration of this magnetic element which are different to those described above.

1. A method for preparing a surface of a substrate based on GaAs (001) in order to make it capable of receiving a ferromagnetic semiconductor, deposited by epitaxy, which is selected from the group consisting of the semiconductors of groups III-V, IV-IV and II-VI of the periodic table with the exception of GaAs and furthermore comprises at least one magnetic element selected from the group consisting of manganese, iron, cobalt, nickel and chromium, wherein the method comprises vacuum deoxidation of said surface under a germanium-based flow so that, at the end of desorption of the arsenic and gallium oxide of said surface, this surface has a monodomain 2×1 reconstruction and is sufficiently planar and depleted of arsenic to avoid any diffusion of arsenic from the substrate to the semiconductor subsequently deposited.

2. The surface preparation method as claimed in claim 1, wherein the method is carried out in a molecular beam epitaxy unit dedicated to the subsequent deposition of said ferromagnetic semiconductor, for example in a unit dedicated to the deposition of a semiconductor of the GeMn type.

3. The surface preparation method as claimed in claim 2, wherein the method furthermore comprises the following steps, carried out in said epitaxy unit before said deoxidation and preferably at a temperature of between 200 and 300° C.:
a) vacuum heating of the substrate, particularly in order to desorb the water and molecules of CO and CO₂ from said surface, then
b) deposition of a germanium thin film on said surface treated in this way.

4. The surface preparation method as claimed in claim 1, wherein said geranium flow at the substrate during said deoxidation is between 0.9×10⁻⁸ Torr and 1.3×10⁻⁸ Torr.

5. The surface preparation method as claimed in claim 1, wherein said germanium flow at the substrate during said deoxidation corresponds to a germanium growth rate of between 0.10 nm/min and 0.20 nm/min.

6. The surface preparation method as claimed in claim 1, wherein the temperature of the substrate during said deoxidation is between 500 and 600° C.,

7. The surface preparation method as claimed in claim 6, wherein upon appearance of said monodomain 2×1 reconstruction for said surface, said germanium flow is stopped and the temperature of the substrate is lowered to a value which is close to that used for the subsequent deposition of the ferromagnetic semiconductor and which is preferably between 80 and 200° C.

8. The surface preparation method as claimed in claim 1, wherein the substrate is subjected to said germanium flow during said deoxidation for a time of between 5 min and 6 min, in order to finally obtain a germanium thin film with a thickness of less than 1 nm on said surface.

9. A substrate based on GaAs (001), a surface of which is capable of receiving a ferromagnetic semiconductor, deposited by epitaxy, which is selected from the group consisting of the semiconductors of groups III-V, IV-IV and II-VI of the periodic table with the exception of GaAs and which furthermore comprises at least one magnetic element selected from the group consisting of manganese, iron, cobalt, nickel and chromium, wherein said surface has a monodomain 2×1 reconstruction and has a sufficiently low arsenic content to avoid any diffusion of arsenic from said surface to this ferromagnetic semiconductor.

10. The substrate as claimed in claim 9, wherein said surface is covered with a germanium thin film with a thickness preferably of less than 1 nm.

11. A method for manufacturing a ferromagnetic semiconductor which is selected from the group consisting of the semiconductors of groups III-V, IV-IV and II-VI of the periodic table with the exception of GaAs and which furthermore comprises at least one magnetic element selected from the group consisting of manganese, iron, cobalt, nickel and chromium, the semiconductor preferably being based on germanium, this method comprising deposition of this semiconductor by molecular beam epitaxy on a substrate the temperature of which during the growth of the crystals is between 80 and 200° C., wherein said method consists in using a substrate as defined in claim 9.

12. The method for manufacturing a ferromagnetic semiconductor as claimed in claim 11, comprising the steps
preparing a surface of a substrate based on GaAs (001) in order to make it capable of receiving a ferromagnetic semiconductor, deposited by epitaxy, which is selected from the group consisting of the semiconductors of groups III-V, IV-IV and II-VI of the periodic table with the exception of GaAs and furthermore comprises at least one magnetic element selected from the group consisting of manganese, iron, cobalt, nickel and chromium; and
vacuum deoxidation of said surface under a germanium-based flow so that, at the end of desorption of the arsenic and gallium oxide of said surface, this surface has a monodomain 2×1 reconstruction and is sufficiently planar and depleted of arsenic to avoid any diffusion of arsenic from the substrate to the semiconductor subsequently deposited.

13. The method for manufacturing a germanium-based ferromagnetic semiconductor as claimed in claim 11, wherein said deposition by epitaxy is carried out in ultrahigh vacuum by evaporation of the germanium and of said at least one magnetic element from solid sources onto the substrate, the semiconductor deposited in this way comprising nanocolumns rich in this element, which are perpendicular to said surface and which are separated from one another by a matrix that has a low content of this element.

14. A ferromagnetic semiconductor which is selected from the group consisting of the semiconductors of groups III-V, IV-IV and II-VI of the periodic table with the exception of GaAs, which furthermore comprises at least one magnetic element selected from the group consisting of manganese, iron, cobalt, nickel and chromium, and which is preferably based on germanium, this semiconductor being deposited by molecular beam epitaxy on a surface of a substrate and comprising nanocolumns rich in this element, which are substantially perpendicular to said surface and which are separated from one another by a matrix that has a low content of this element, wherein said substrate is as defined in claim 9.

15. The use of a ferromagnetic semiconductor as claimed in claim 14 for injecting spins into this substrate based on GaAs (001), for example so that this substrate emits light in the form of light-emitting diodes while combining the emission of the light with selective spin-polarized injection.

16. The use of a ferromagnetic semiconductor as claimed in claim 14 for producing transistors operating with spin-polarized current, this current flowing in the semiconductor deposited on this substrate based on GaAs (001).

17. The method for manufacturing a germanium-based ferromagnetic semiconductor as claimed in claim 1, wherein the semiconductor is based on GeMn and the step of deposition of the semiconductor by molecular beam epitaxy on a substrate is carried out at a temperature between 90 and 100° C.
